(19) United States
(12) Patent Application Publication
(10) Pub. No.: US 2024/0316592 A1
(43) Pub. Date: Sep. 26, 2024

(54) FILM FORMING APPARATUS

(71) Applicant: Tokyo Electron Limited, Tokyo (JP)

(72) Inventors: Tatsuya YAMAGUCHI, Nirasaki City (JP); Syuji NOZAWA, Nirasaki City (JP)

(21) Appl. No.: 18/608,057

(22) Filed: Mar. 18, 2024

(30) Foreign Application Priority Data
Mar. 22, 2023 (JP) 2023-045407

(51) Int. Cl. B05D 1/00; C08G 18/50; C09D 175/04

(52) U.S. Cl. CPC B05D 1/60; C08G 18/5045; C09D 175/04; B05D 2503/00; C08G 2150/50

(57) ABSTRACT

A film forming apparatus includes: a first vaporizer configured to vaporize a first monomer containing isocyanate; a second vaporizer configured to vaporize a second monomer that reacts with the first monomer to form a polymer; a first pipe connected to the first vaporizer; a second pipe connected to the second vaporizer; and a chamber having an internal space for accommodating a substrate, connected to the first pipe and the second pipe, and configured to form a polymer film on the substrate by vapor deposition polymerization using the first monomer and the second monomer. The first vaporizer heats the first monomer to a temperature of 120 degrees C. or less. A pressure inside the first vaporizer is equal to or higher than a pressure in the chamber. A differential pressure between the pressure inside the first vaporizer and the pressure in the chamber is 1 Torr or less.

### CROSS-REFERENCE TO RELATED APPLICATION

This application is based upon and claims the benefit of priority from Japanese Patent Application No. 2023-045407, filed on Mar. 22, 2023, the entire contents of which are incorporated herein by reference.

### TECHNICAL FIELD

Various aspects and embodiments of the present disclosure relate to a film forming apparatus.

### BACKGROUND

Patent Document 1 below discloses “a case where plural types of raw materials used to form a film on a workpiece W are two types of raw materials, for example, a raw material A as a first raw material and a raw material B as a second raw material, is described. For example, in a case where a polyurea film is formed on the workpiece W, the raw material A and the raw material B are, for example, diisocyanate and diamine. In a film forming apparatus 1, the polyurea film is formed on a front surface of the workpiece W by subjecting the diisocyanate and the diamine to vapor deposition polymerization on the front surface of the workpiece W.”

### PRIOR ART DOCUMENTS

### Patent Documents

Patent Document 1: Japanese Patent Laid-Open Publication No. 2019-218616

### SUMMARY

According to one embodiment of the present disclosure, a film forming apparatus includes: a first vaporizer configured to vaporize a first monomer containing isocyanate; a second vaporizer configured to vaporize a second monomer that reacts with the first monomer to form a polymer; a first pipe connected to the first vaporizer; a second pipe connected to the second vaporizer; and a chamber having an internal space for accommodating a substrate, connected to the first pipe and the second pipe, and configured to form a polymer film on the substrate by vapor deposition polymerization using the first monomer supplied to the internal space via the first pipe and the second monomer supplied to the internal space via the second pipe. The first vaporizer heats the first monomer to a temperature of 120 degrees C. or less. A pressure inside the first vaporizer is equal to or higher than a pressure in the chamber. A differential pressure between the pressure inside the first vaporizer and the pressure in the chamber is 1 Torr or less.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating an example of a film forming apparatus according to an embodiment of the present disclosure.

FIG. 2 is a diagram illustrating an example of a change in mass of isocyanate.

FIG. 3 is a diagram illustrating an example of a relationship between a pressure in a chamber and a film formation rate.

FIG. 4 is a diagram illustrating an example of a relationship between the pressure in the chamber and a uniformity of a film thickness.

FIG. 5 is a diagram illustrating an example of a relationship among the pressure in the chamber, the film formation rate, and the uniformity of the film thickness when supply amounts of isocyanate and amine are controlled to be constant.

FIG. 6 is a diagram illustrating an example of a relationship between a pressure in a vaporizer and a vaporization rate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of a film forming apparatus will be described in detail based on the drawings. The disclosed film forming apparatus is not limited to the embodiment below.

When forming a polymer film on a substrate by vapor deposition polymerization, a film formation rate may be increased by increasing the amount of monomer gas supplied to the inside of a chamber. When the temperature of the monomer is increased in a vaporizer, the vapor pressure of the monomer is increased, and the amount of the monomer gas supplied to the inside of the chamber may be increased. However, when the temperature of the monomer is raised too much, the monomer may deteriorate due to heat depending on the monomer, resulting in a decrease in volatility. When the volatility of the monomer is decreased, the supply amount of the monomer gas to the inside of the chamber is conversely decreased.

Furthermore, in order to increase the amount of the monomer gas supplied to the inside of the chamber, increasing the flow rate of carrier gas in the vaporizer may be considered. In this case, although the supply amount of the monomer to the inside of the chamber increases, the supply amount of the carrier gas also increases together with the monomer, so the concentration of the monomer in the chamber does not increase much. Also, increasing the pressure of the chamber in order to increase the amount of monomer in the chamber can be considered, but increasing the pressure of the chamber deteriorates uniformity of film thickness.

Therefore, the present disclosure provides a technique capable of improving film formation efficiency while maintaining uniformity of a film thickness.

### [Configuration of Film Forming Apparatus 10]

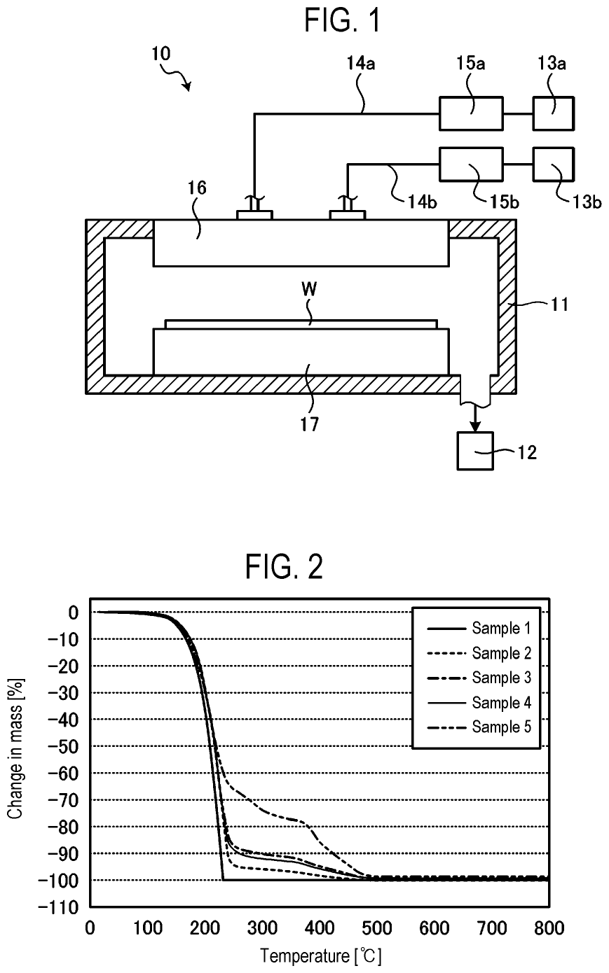

FIG. 1 is a schematic diagram illustrating an example of a film forming apparatus 10 according to an embodiment of the present disclosure. The film forming apparatus 10 includes a chamber 11, an exhauster 12, a shower head 16, and a stage 17. In the present embodiment, the film forming apparatus 10 is, for example, a chemical vapor deposition (CVD) apparatus.

The exhauster 12 includes a vacuum pump that exhausts a gas in the chamber 11 and a pressure adjustment valve that adjusts a pressure in the chamber 11. The inside of the chamber 11 is controlled by the exhauster 12 to be a vacuum atmosphere with a predetermined pressure.

Multiple types of raw material monomers are supplied to the chamber 11 via the shower head 16. In the present embodiment, the multiple types of raw material monomers are, for example, isocyanate and amine. A raw material supply source 13a accommodating the isocyanate in liquid form is connected to the shower head 16 via a pipe 14a. Further, a raw material supply source 13b accommodating the amine in liquid form is connected to the shower head 16 via a pipe 14b. The isocyanate is an example of a first monomer, and the amine is an example of a second monomer. The pipe 14a is an example of a first pipe, and the pipe 14b is an example of a second pipe.

Isocyanate liquid supplied from the raw material supply source 13a is vaporized by a vaporizer 15a interposed in the pipe 14a. Isocyanate vapor vaporized by the vaporizer 15a is introduced into the shower head 16 via the pipe 14a. Further, amine liquid supplied from the raw material supply source 13b is vaporized by a vaporizer 15b interposed in the pipe 14b. Amine vapor vaporized by the vaporizer 15b is introduced into the shower head 16 via the pipe 14b. The vaporizer 15a and the vaporizer 15b vaporize the raw material monomers by, for example, a bubbling method. The vaporizer 15a is an example of a first vaporizer, and the vaporizer 15b is an example of a second vaporizer.

The shower head 16 is provided, for example, in an upper portion of the chamber 11, and has discharge holes formed on a lower surface of the shower head. The shower head 16 discharges the isocyanate vapor introduced via the pipe 14a and the amine vapor introduced via the pipe 14b into the chamber 11 in the form of a shower from respective separate discharge holes.

The stage 17 is provided in the chamber 11. The stage 17 has a temperature adjustment mechanism, which is not shown. A substrate W as a film formation target is placed on the stage 17. The stage 17 controls the temperature of the substrate W by the temperature adjustment mechanism so that the temperature of the substrate W becomes a temperature suitable for vapor deposition polymerization of the raw material monomers supplied respectively from the raw material supply source 13a and the raw material supply source 13b. The temperature suitable for vapor deposition polymerization may be determined depending on the type of the raw material monomer. The temperature suitable for vapor deposition polymerization is, for example, a temperature in a range of 60 degrees C. to 100 degrees C.

Using the film forming apparatus 10, an organic film is deposited on the surface of the substrate W by causing a vapor deposition polymerization reaction of two types of raw material monomers on the surface of the substrate W. When the two types of raw material monomers are the isocyanate and the amine, a polyurea polymer film is deposited on the surface of the substrate W.

Film forming conditions in the present embodiment are, for example, as follows.
Temperature of substrate W: 80 degrees C.
Temperature of isocyanate in vaporizer 15a: 120 degrees C.
Pressure in vaporizer 15a: 1 Torr (133 Pa)
Flow rate of carrier gas in vaporizer 15a: 50 sccm (8.33×10⁻⁷ m³/s)
Flow rate of isocyanate vapor: 10 sccm
Temperature of amine in vaporizer 15b: 120 degrees C.
Pressure in vaporizer 15b: 1 Torr
Flow rate of carrier gas in vaporizer 15b: 50 sccm
Flow rate of amine vapor: 20 sccm
Pressure in chamber 11: 1 Torr
Flow rate of additive gas in chamber 11: 100 sccm
The carrier gas and additive gas are nitrogen gas.

### [Thermal Change of Isocyanate]

When forming a polymer film on the substrate W by vapor deposition polymerization, the film formation rate may be increased by increasing the amount of monomer gas supplied to the inside of the chamber 11. When the temperature of monomer is increased in the vaporizer 15a and the vaporizer 15b, the vapor pressure of the monomer is increased, and the amount of monomer gas supplied to the inside of the chamber may be increased. However, there is monomer, for example, isocyanate, that deteriorates due to heat and decreases volatility if the temperature of the isocyanate is raised too much. When volatility is decreased, the supply amount of the monomer gas to the inside of the chamber is conversely decreased.

FIG. 2 is a diagram illustrating an example of a change in mass of isocyanate. FIG. 2 illustrates a change in mass of the isocyanate. In FIG. 2, sample 1 illustrates a change in mass of the isocyanate stored at room temperature, sample 2 illustrates a change in mass of the isocyanate after being left at 150 degrees C. for one week, and sample 3 illustrates a change in mass of the isocyanate after being left at 150 degrees C. for two weeks. Further, in FIG. 2, sample 4 illustrates a change in mass of the isocyanate after being left at 150 degrees C. for 4 weeks, and sample 5 illustrates a change in mass of the isocyanate after being left at 150 degrees C. for 8 weeks. Sample 5 was discolored in appearance and was found to be deteriorated in quality.

As illustrated in FIG. 2, when the isocyanate is heated to 150 degrees C. or higher, the isocyanate self-polymerizes by heat and changes into another substance having low volatility. Therefore, it is difficult to increase the supply amount of the isocyanate by heating the isocyanate and thus increasing vapor pressure.

Thereby, it is desirable to handle the first monomer including the isocyanate in a temperature range of, for example, 120 degrees C. or lower.

### [Relationship Between Pressure in Chamber 11 and Film Formation Rate]

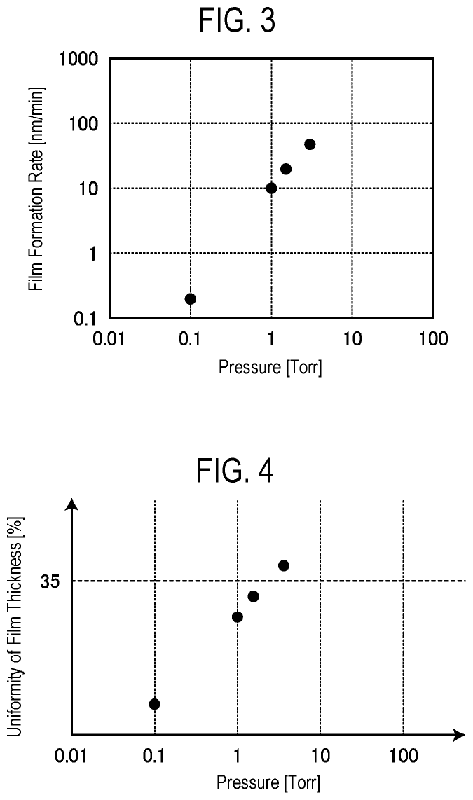

FIG. 3 is a diagram illustrating an example of a relationship between a pressure in the chamber 11 and a film formation rate. In the experiment shown in FIG. 3, the pressure in the chamber 11 was controlled by controlling the pressure adjustment valve in the exhauster 12.

As illustrated in FIG. 3, as the pressure in the chamber 11 becomes higher, the film formation rate becomes higher, and as the pressure in the chamber 11 becomes lower, the film formation rate becomes lower. In the example of FIG. 3, when the pressure in the chamber 11 was 1 Torr, the film formation rate was 10 nm/min.

From the viewpoint of throughput, it is desirable that the film formation rate is 10 nm/min or more. Thereby, referring to FIG. 3, it is desirable that the pressure in the chamber 11 is 1 Torr or more.

### [Relationship Between Pressure in Chamber 11 and Uniformity of Film Thickness]

FIG. 4 is a diagram illustrating an example of a relationship between pressure in the chamber 11 and uniformity of film thickness. In the experiment shown in FIG. 4, the pressure in the chamber 11 was controlled by controlling the pressure adjustment valve in the exhauster 12.

As illustrated in FIG. 4, as the pressure in the chamber 11 increases, uniformity of film thickness deteriorates, and as the pressure in the chamber 11 decreases, uniformity of film thickness is improved. As illustrated in FIG. 4, when the pressure in the chamber 11 was 1.5 Torr, the uniformity of the film thickness was 30.9%, and when the pressure in the chamber 11 was 3.0 Torr, the uniformity of the film thickness was 38.5%.

From the viewpoint of suppressing variations in quality of semiconductor devices formed on the substrate W, it is desirable that the uniformity of the film thickness is less than 35%. Thereby, referring to FIG. 4, it is desirable that the pressure in the chamber 11 is 1.5 Torr or less.

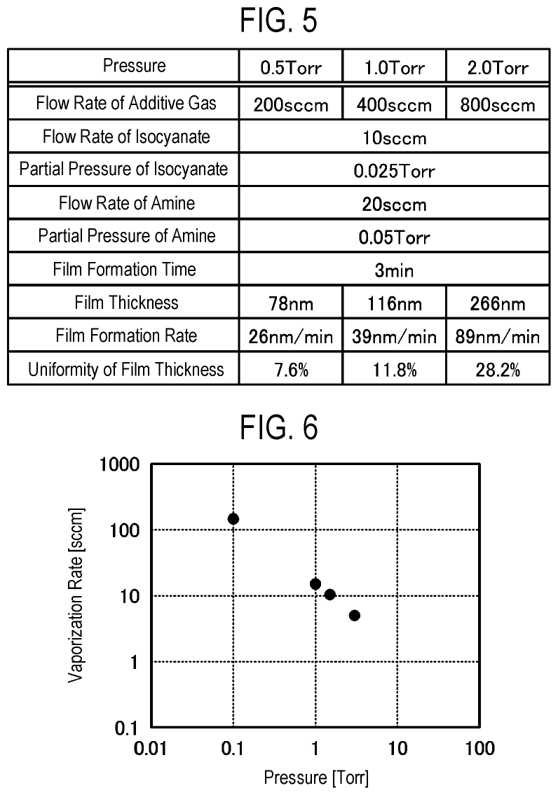

FIG. 5 is a diagram illustrating an example of a relationship among the pressure in the chamber 11, the film formation rate, and the uniformity of the film thickness when the supply amounts of isocyanate and amine are controlled to be constant. In the experiment shown in FIG. 5, the pressure in the chamber 11 was controlled by changing the flow rate of an additive gas while constantly maintaining an opening degree of the pressure adjustment valve in the exhauster 12. The additive gas is nitrogen gas.

As illustrated in FIG. 5, even when the supply amounts of the isocyanate and the amine are kept constant, as the pressure in the chamber 11 increases, the film formation rate increases but the uniformity of the film thickness is deteriorated. On the other hand, even when the supply amounts of the isocyanate and the amine are kept constant, as the pressure in the chamber 11 decreases, the film formation rate decreases but the uniformity of the film thickness is improved. In the example of FIG. 5, the value of the film formation rate is larger than the value shown in FIG. 3, but this is because the film formation rate and the uniformity were optimized by a chamber environment.

### [Relationship Between Pressure in Vaporizer 15a and Vaporization Rate]

FIG. 6 is a diagram illustrating an example of a relationship between a pressure in the vaporizer 15a and the vaporization rate. In the vaporizer 15a that vaporizes the isocyanate, the pressure in the vaporizer 15a was changed to examine the vaporization rate (flow rate) of the isocyanate output from the vaporizer 15a.

As illustrated in FIG. 6, as the pressure in the vaporizer 15a increases, the vaporization rate of the isocyanate decreases, and as the pressure in the vaporizer 15a decreases, the vaporization rate of the isocyanate increases. Referring to FIG. 6, when the pressure in the vaporizer 15a is 2 Torr, the vaporization rate is 10 sccm.

It is desirable that the supply amount (vaporization rate) of the isocyanate is 10 sccm or more from the viewpoint of film formation rate. Referring to FIG. 6, when the pressure in the vaporizer 15a is 2 Torr or less, the vaporization rate of the isocyanate is 10 sccm or more. From the viewpoint of film formation rate, it is desirable that the pressure in the vaporizer 15a is 2 Torr or less.

Here, from the results illustrated in FIGS. 3 and 4, it is desirable that the pressure in the chamber 11 is in a range of 1 Torr or more and 2 Torr or less. From the result illustrated in FIG. 6, it is desirable that the pressure in the vaporizer 15a is 2 Torr or less. From these results, it is desirable that the differential pressure between the internal pressure of the vaporizer 15a and the internal pressure of the chamber 11 is 1 Torr or less. The pipe 14a connecting the vaporizer 15a and the chamber 11 is configured to have conductance such that the differential pressure between the internal pressure of the vaporizer 15a and the internal pressure of the chamber 11 is 1 Torr or less. Further, the internal pressure of the vaporizer 15a is higher than the internal pressure of the chamber 11.

Hereinabove, the embodiment has been described. As described above, the film forming apparatus in the present embodiment includes a first vaporizer (vaporizer 15a), a second vaporizer (vaporizer 15b), a first pipe (pipe 14a), a second pipe (pipe 14b), and a chamber (chamber 11). The first vaporizer vaporizes a first monomer including isocyanate. The second vaporizer vaporizes a second monomer that reacts with the first monomer to form a polymer. The first pipe is connected to the first vaporizer. The second pipe is connected to the second vaporizer. The chamber has an internal space in which a substrate is accommodated and is connected to the first pipe and the second pipe. Further, the chamber forms a polymer film on the surface by vapor deposition polymerization using the first monomer supplied to the internal space via the first pipe and the second monomer supplied to the internal space via the second pipe. The first vaporizer heats the first monomer to a temperature of 120 degrees C. or less. The pressure in the first vaporizer is equal to or higher than the pressure in the chamber, and the differential pressure between the pressure inside the first vaporizer and the pressure in the chamber 1 Torr or less. Thereby, the efficiency of film formation may be improved while maintaining uniformity of the film thickness.

In the embodiment described above, the pressure in the chamber is in a range of 1 Torr or more and 2 Torr or less. Thereby, the efficiency of film formation may be improved while maintaining uniformity of the film thickness.

Further, in the embodiment described above, the internal pressure of the first vaporizer is 2 Torr or less. Thereby, the efficiency of film formation may be improved while maintaining uniformity of the film thickness.

Further, in the embodiment described above, the first vaporizer vaporizes the first monomer using a bubbling method. Thereby, the first monomer may be efficiently vaporized.

Further, in the embodiment described above, the vaporization rate of the first vaporizer is 10 sccm or more. Thereby, a sufficient amount of the first monomer may be supplied to the inside of the chamber.

Furthermore, in the embodiment described above, the film formation rate on the substrate in the chamber is 10 nm/min or more. Thereby, throughput may be improved.

Additionally, in the embodiment described above, the thickness uniformity of the polymer film formed on the substrate in the chamber is less than 35%. Thereby, variations in quality of semiconductor devices formed on the substrate W may be suppressed.

Furthermore, in the embodiment described above, the second monomer contains amine, and the polymer film formed on the substrate contains a urea bond. Thereby, a polyurea film may be easily formed on the substrate W.

### [Others]

The technology disclosed in the present application is not limited to the embodiment described above and may be modified in many ways within the scope of the gist thereof.

Further, in the embodiment described above, the pipe 14a connecting the vaporizer 15a and the chamber 11 is configured to have conductance such that the differential pressure between the internal pressure of the vaporizer 15a and the internal pressure of the chamber 11 is 1 Torr or less. However, the disclosed technology is not limited thereto. As another embodiment, the pipe 14a connecting the vaporizer 15a and the chamber 11 may be provided with a valve that adjusts the conductance of the pipe 14a. Thereby, the conductance between the vaporizer 15a and the chamber 11 may be easily adjusted so that the differential pressure between the internal pressure of the vaporizer 15a and the internal pressure of the chamber 11 is 1 Torr or less.

Further, the film forming apparatus 10 in the embodiment described above forms the polymer film containing the urea bond on the substrate by vapor deposition polymerization using the first monomer containing the isocyanate and the second monomer containing the amine. However, the disclosed technology is not limited thereto. Alternatively, the film forming apparatus 10 may form the polymer film containing the urethane bond on the substrate by vapor deposition polymerization using the first monomer containing the isocyanate and the second monomer containing alcohol.

The embodiments disclosed this time should be considered in all aspects to be illustrative and not restrictive. Indeed, the embodiments described above may be implemented in various forms. Further, the above-described embodiments may be omitted, replaced, or modified in various forms without departing from the scope and spirit of the appended claims.

Further, regarding the above embodiment, the following supplementary notes are further disclosed.

### (Supplementary Note 1)

A film forming apparatus includes:
a first vaporizer that vaporizes a first monomer containing isocyanate;
a second vaporizer that vaporizes a second monomer that reacts with the first monomer to form a polymer;
a first pipe connected to the first vaporizer, and a second pipe connected to the second vaporizer; and
a chamber having an internal space for accommodating a substrate, connected to the first pipe and the second pipe, and configured to form a polymer film on the substrate by vapor deposition polymerization using the first monomer supplied to the internal space via the first pipe and the second monomer supplied to the internal space via the second pipe,
wherein the first vaporizer heats the first monomer to a temperature of 120 degrees C. or less,
wherein a pressure inside the first vaporizer is equal to or higher than internal pressure of the chamber, and
wherein a differential pressure between the internal pressure of the first vaporizer and the internal pressure of the chamber is 1 Torr or less.

### (Supplementary Note 2)

The film forming apparatus according to Supplementary Note 1, wherein the pressure in the chamber is in a range of 1 Torr or more and 2 Torr or less.

### (Supplementary Note 3)

The film forming apparatus according to Supplementary Note 1 or 2, wherein the pressure inside the first vaporizer is 2 Torr or less.

### (Supplementary Note 4)

The film forming apparatus according to any one of Supplementary Notes 1 to 3, wherein the first vaporizer vaporizes the first monomer by a bubbling method.

### (Supplementary Note 5)

The film forming apparatus according to any one of Supplementary Notes 1 to 4, wherein a vaporization rate of the first vaporizer is 10 sccm or more.

### (Supplementary Note 6)

The film forming apparatus according to any one of Supplementary Notes 1 to 5, wherein a film forming rate on the substrate in the chamber is 10 nm/min or more.

### (Supplementary Note 7)

The film forming apparatus according to any one of Supplementary Notes 1 to 6, wherein a thickness uniformity of the polymer film formed on the substrate in the chamber is less than 35%.

### (Supplementary Note 8)

The film forming apparatus according to any one of Supplementary Notes 1 to 7, wherein a valve that adjusts conductance of the first pipe is installed in the first pipe.

### (Supplementary Note 9)

The film forming apparatus according to any one of Supplementary Notes 1 to 8, wherein the second monomer includes amine, and the polymer film includes a urea bond.

### (Supplementary Note 10)

The film forming apparatus according to any one of Supplementary Notes 1 to 8, wherein the second monomer is an alcohol, and the polymer film includes a urethane bond.

According to various aspects and embodiments of the present disclosure, efficiency of film formation may be improved while maintaining uniformity of the film thickness.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus, comprising:
a first vaporizer configured to vaporize a first monomer containing isocyanate;
a second vaporizer configured to vaporize a second monomer that reacts with the first monomer to form a polymer;
a first pipe connected to the first vaporizer;
a second pipe connected to the second vaporizer; and
a chamber having an internal space for accommodating a substrate, connected to the first pipe and the second pipe, and configured to form a polymer film on the substrate by vapor deposition polymerization using the first monomer supplied to the internal space via the first pipe and the second monomer supplied to the internal space via the second pipe,
wherein the first vaporizer heats the first monomer to a temperature of 120 degrees C. or less,
wherein a pressure inside the first vaporizer is equal to or higher than a pressure in the chamber, and
wherein a differential pressure between the pressure inside the first vaporizer and the pressure in the chamber is 1 Torr or less.

2. The film forming apparatus of claim 1, wherein the pressure in the chamber is in a range of 1 Torr or more and 2 Torr or less.

3. The film forming apparatus of claim 2, wherein the pressure inside the first vaporizer is 2 Torr or less.

4. The film forming apparatus of claim 1, wherein the first vaporizer vaporizes the first monomer by a bubbling method.

5. The film forming apparatus of claim 1, wherein a vaporization rate of the first vaporizer is 10 sccm or more.

6. The film forming apparatus of claim 1, wherein a film forming rate on the substrate in the chamber is 10 nm/min or more.

7. The film forming apparatus of claim 1, wherein a thickness uniformity of the polymer film formed on the substrate in the chamber is less than 35%.

8. The film forming apparatus of claim 1, wherein a valve configured to adjust conductance of the first pipe is installed in the first pipe.

9. The film forming apparatus of claim 1, wherein the second monomer includes amine, and
wherein the polymer film includes a urea bond.

10. The film forming apparatus of claim 1, wherein the second monomer is an alcohol, and
wherein the polymer film includes a urethane bond.

11. The film forming apparatus of claim 1, wherein the pressure inside the first vaporizer is 2 Torr or less.
